(19) United States
(12) Patent Application Publication
(10) Pub. No.: US 2026/0107466 A1
(43) Pub. Date: Apr. 16, 2026

(54) SEMICONDUCTOR DEVICE AND MANUFACTURING METHOD OF A SEMICONDUCTOR DEVICE

(71) Applicant: SK hynix Inc., Icheon-si Gyeonggi-do (KR)

(72) Inventors: Hyun Kyu LEE, Icheon-si Gyeonggi-do (KR); Sun Kak HWANG, Icheon-si Gyeonggi-do (KR); Won Jun KIM, Icheon-si Gyeonggi-do (KR); Dong Chul YOO, Icheon-si Gyeonggi-do (KR)

(73) Assignee: SK hynix Inc., Icheon-si Gyeonggi-do (KR)

(21) Appl. No.: 19/019,915

(22) Filed: Jan. 14, 2025

(30) Foreign Application Priority Data
Oct. 11, 2024 (KR) 10-2024-0138767

(51) Int. Cl. H10B 43/27; H10B 41/27

(52) U.S. Cl. CPC H10B 43/27; H10B 41/27

(57) ABSTRACT

A semiconductor device includes a gate structure including alternately stacked insulating layers and conductive layers. The semiconductor device also includes a channel layer extending through the gate structure, the channel layer including a first portion including metal atoms at a first concentration and a second portion including metal atoms at a second concentration different from the first concentration. The semiconductor device further includes an insulating core in the channel layer and a capping layer on the insulating core. The first portion is on the second portion, and the boundary between the first portion and the second portion is between an upper surface and a lower surface of an uppermost insulating layer of the insulating layers.

### CROSS-REFERENCE TO RELATED APPLICATION

This application claims priority under 35 U.S.C. § 119(a) to Korean Patent Application No. 10-2024-0138767, filed in the Korean Intellectual Property Office on Oct. 11, 2024, which application is incorporated herein by reference in its entirety.

### BACKGROUND

### 1. Technical Field

Embodiments of the present disclosure relate to an electronic device and a manufacturing method of the electronic device, and more particularly, to a semiconductor device and a manufacturing method of the semiconductor device.

### 2. Related Art

The degree of integration of a semiconductor device is mainly determined by an area occupied by a unit memory cell of the semiconductor device. Recently, as the improvement in the degree of integration for semiconductor devices for which memory cells formed in a single layer on a substrate reaches a limit, three-dimensional semiconductor devices for which memory cells are stacked on a substrate has been proposed. Furthermore, to improve the operational reliability of such semiconductor devices, various structures and manufacturing methods have been developed.

### SUMMARY

In an embodiment, a semiconductor device may include: a gate structure including alternately stacked insulating layers and conductive layers; a channel layer extending through the gate structure, the channel layer including a first portion including metal atoms at a first concentration and a second portion including metal atoms at a second concentration different from the first concentration; an insulating core inside the channel layer; and a capping layer on the insulating core. The first portion may be on the second portion, and the boundary between the first portion and the second portion may be between an upper surface and a lower surface of an uppermost insulating layer of the insulating layers.

In an embodiment, a semiconductor device may include: a gate structure including alternately stacked insulating layers and conductive layers; a channel layer extending through the gate structure, the channel layer including a first portion having a first grain size and a second portion having a second grain size different from the first grain size; an insulating core inside the channel layer at a level corresponding to the second portion; and a capping layer on the insulating core at a level corresponding to the first portion.

In an embodiment, a manufacturing method of a semiconductor device may include: forming a stack by alternately stacking first material layers and second material layers; forming a channel hole extending through the stack; forming a preliminary channel layer in the channel hole; forming a first channel layer by crystallizing a first portion of the preliminary channel layer; doping the first channel layer and the preliminary channel layer with metal atoms; forming a second channel layer by crystallizing a second portion of the preliminary channel layer; forming an insulating core inside the first channel layer and the second channel layer; and forming a capping layer on the insulating core.

### BRIEF DESCRIPTION OF THE DRAWINGS

FIGS. 1A and 1B are diagrams for describing a semiconductor device in accordance with an embodiment.

FIGS. 2, 3, 4, 5, 6, 7, 8, 9A, and 9B are diagrams for describing a manufacturing method of a semiconductor device in accordance with an embodiment.

FIG. 10 is a diagram for describing a semiconductor device in accordance with an embodiment.

FIG. 11 is a diagram for describing a semiconductor device in accordance with an embodiment.

FIG. 12 is a diagram for describing a semiconductor device in accordance with an embodiment.

### DETAILED DESCRIPTION

Various embodiments are directed to a semiconductor device having a stable structure and improved characteristics and a manufacturing method of the semiconductor device.

According to the present technology, it is possible to provide a semiconductor device having a stable structure and improved reliability.

Hereafter, embodiments in accordance with the technical spirit of the present disclosure are described with reference to the accompanying drawings.

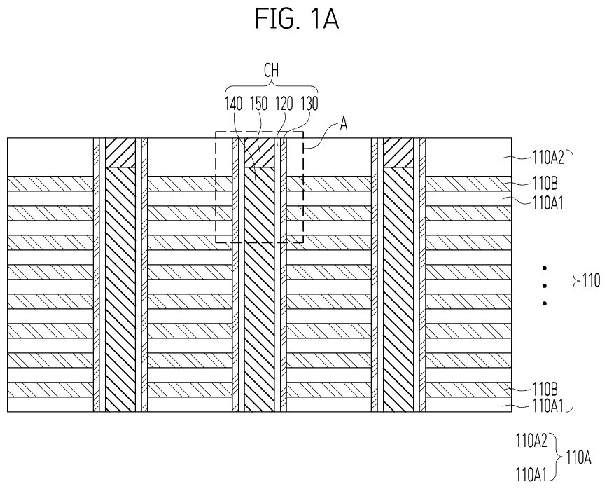

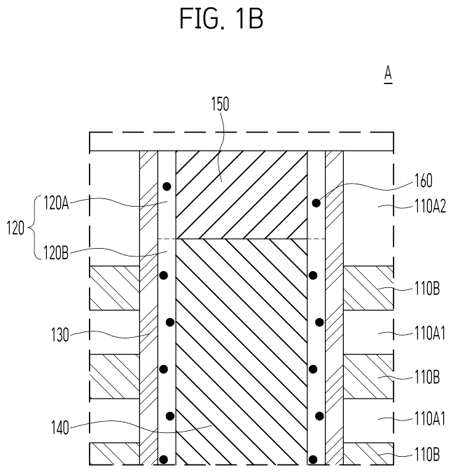

FIGS. 1A and 1B are diagrams for describing a semiconductor device in accordance with an embodiment. FIG. 1A is a cross-sectional view, and FIG. 1B is an enlarged view of region A of FIG. 1A.

Referring to FIGS. 1A and 1B, the semiconductor device may include a gate structure 110 and channel structures CH.

The gate structure 110 may include insulating layers 110A and conductive layers 110B that are alternately stacked. The insulating layers 110A may include an uppermost insulating layer 110A2 located at the uppermost portion among the insulating layers 110A and the remaining insulating layers 110A1. Here, the uppermost insulating layer 110A2 may be thicker than the remaining insulating layers 110A1. The insulating layers 110A may each include an insulating material, such as an oxide. The conductive layers 110B may each include a conductive material, such as tungsten, molybdenum, or polysilicon.

The conductive layers 110B may be gate lines, such as a source select line, word lines, and a drain select line. A source select transistor, memory cells, or a drain select transistor may be in regions where the channel structures CH and the conductive layers 110B intersect each other. For example, at least one source select transistor, a plurality of memory cells, and at least one drain select transistor that are stacked along the channel structure CH may constitute a memory string.

The channel structures CH may extend through the gate structure 110. Each of the channel structures CH may include at least one of a channel layer 120, a memory layer 130, an insulating core 140, and a capping layer 150.

The channel layer 120 may include a first portion 120A and a second portion 120B located beneath the first portion 120A. Here, the boundary between the first portion 120A and the second portion 120B may be at a height between an upper surface and a lower surface of the uppermost insulating layer 110A2.

The first portion 120A and the second portion 120B may include substantially the same material or different materials. For example, the first portion 120A and the second portion 120B may each include polysilicon. Here, the first portion 120A may include polysilicon that does not include a metal silicide, and the second portion 120B may include polysilicon that includes a metal silicide. Here, the metal silicide may include nickel silicide (NiSi₂). This is because the first portion 120A and the second portion 120B may be formed in different manners in a process of forming the channel layer 120.

The first portion 120A and the second portion 120B may include metal atoms 160 at different concentrations. For example, the first portion 120A may include metal atoms 160 at a first concentration. The second portion 120B may include metal atoms 160 at a second concentration different from the first concentration. Here, the first concentration may be lower than the second concentration. The metal atoms 160 may include nickel (Ni) atoms. This is because the metal atoms 160 of the first portion 120A may move to a region of the second portion 120B in the process of forming the channel layer 120.

However, the present disclosure is not limited thereto, and the first portion 120A and/or the second portion 120B might not include the metal atoms 160. For example, the first portion 120A might not include metal atoms, and the second portion 120B may include the metal atoms 160 at the second concentration.

The first portion 120A may have a first grain size. The second portion 120B may have a second grain size different from the first grain size. Here, the second grain size may be greater than the first grain size. This is because metal atoms 160 of the first portion 120A may move to the region of the second portion 120B and react with amorphous silicon to form metal silicide, and the amorphous silicon forms the second portion 120B while being crystallized with the metal silicide as a nucleus, in the process of forming the channel layer 120. Accordingly, the second portion 120B may have a relatively greater grain size than the first portion 120A, and thus, electric current may flow smoothly in the second portion 120B.

The memory layer 130 may surround the channel layer 120. The memory layer 130 may include multiple layers. For example, the memory layer 130 may include a tunneling layer, a data storage layer, and a blocking layer. Here, the tunneling layer and the blocking layer may each include an oxide, and the data storage layer may include a floating gate, a nitride layer, a variable resistance layer, or the like.

The insulating core 140 may be inside the channel layer 120. For example, the insulating core 140 may be located at a height corresponding to the second portion 120B of the channel layer 120. The insulating core 140 may include an insulating material, such as an oxide.

A cleaning process may be used in forming the insulating core 140, and a dry cleaning method may be implemented as the cleaning process. When the channel layer 120 includes polysilicon including metal silicide, the metal atoms 160 may accumulate in the vicinity of an upper surface of the channel layer 120. In such a case, when the dry cleaning method is used to form the insulating core 140, the upper surface of the channel layer 120 may be damaged.

According to an embodiment of the present disclosure, the first portion 120A may correspond to the vicinity of the upper surface of the channel layer 120 and may include polysilicon that does not include a metal silicide. In such a case, even though the dry cleaning method is used to form the insulating core 140, damage to the upper surface of the channel layer 120 may be prevented or mitigated.

The capping layer 150 may be inside the channel layer 120. The capping layer 150 may be on the insulating core 140. For example, the boundary between the capping layer 150 and the insulating core 140 may be at a height between the upper surface and the lower surface of the uppermost insulating layer 110A2. The capping layer 150 may be located at a height corresponding to the first portion 120A of the channel layer 120. The capping layer 150 may include polysilicon or the like.

A case where the boundary between the first portion 120A and the second portion 120B of the channel layer 120 is at a height between the upper surface and the lower surface of the uppermost insulating layer 110A2 is illustrated in FIGS. 1A and 1B, but the present disclosure is not limited thereto. For example, the boundary between the first portion 120A and the second portion 120B of the channel layer 120 may converge on the upper surface of the uppermost insulating layer 110A2. In such a case, the channel layer 120 may include a very small first portion 120A, and the channel layer 120 may exist mostly as the second portion 120B. However, even in such a case, locations of the insulating core 140 and the capping layer 150 might not change.

According to the structure described above, the channel layer 120 may include the first portion 120A including polysilicon that does not include metal silicide and the second portion 120B including polysilicon that includes metal silicide. Accordingly, it is possible to prevent the first portion 120A of the channel layer 120 from being damaged, or to mitigate damage, in a process of manufacturing a semiconductor device.

In addition, the first portion 120A may have a first grain size, and the second portion 120B may have a second grain size greater than the first grain size. Accordingly, electric current may flow more smoothly in the second portion 120B.

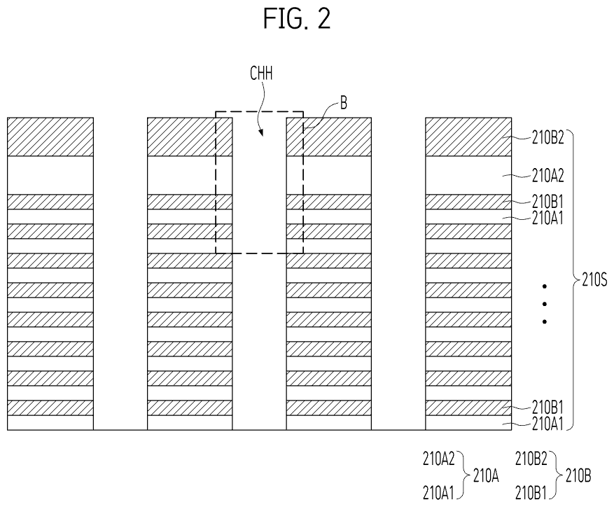

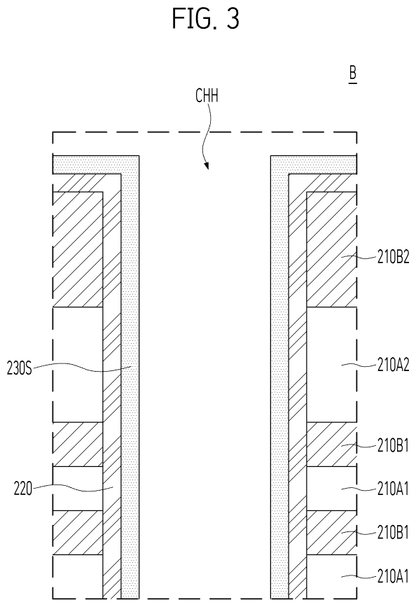

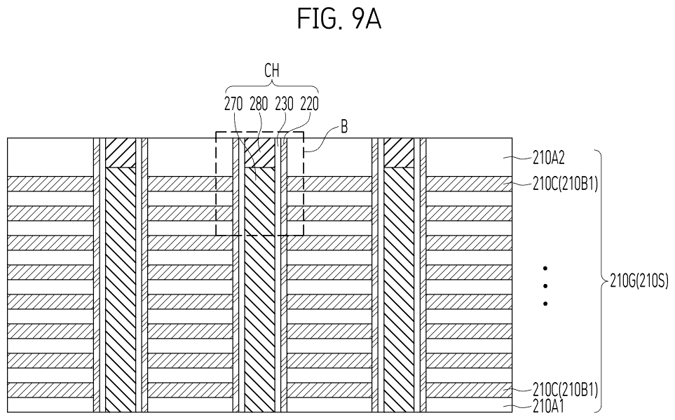

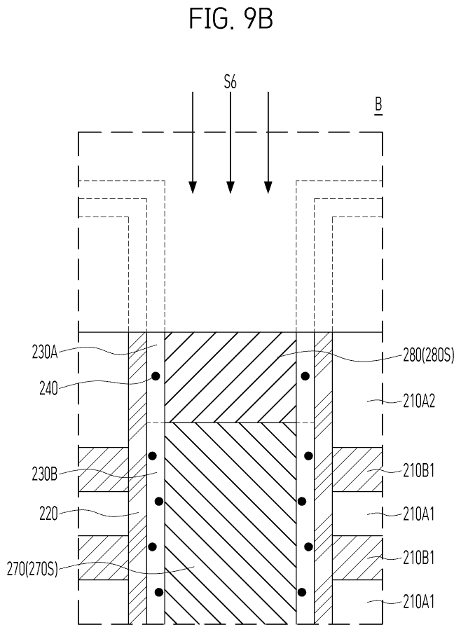

FIGS. 2 to 8, 9A, and 9B are diagrams for describing a manufacturing method of a semiconductor device in accordance with an embodiment. FIGS. 2 and 9A are cross-sectional views, FIGS. 3 to 8 are enlarged views of region B in processes after FIG. 2, and FIG. 9B is an enlarged view of FIG. 9A. Hereinafter, content already described is not repeated.

Referring to FIG. 2, a stack 210S may be formed by alternately stacking first material layers 210A and second material layers 210B. The first material layers 210A may include an uppermost first material layer 210A2 and the remaining first material layers 210A1. The second material layers 210B may include an uppermost second material layer 210B2 and the remaining second material layers 210B1. Here, the uppermost second material layer 210B2 may be a sacrificial layer. The first material layers 210A may each include an insulating material, such as an oxide, and the second material layers 210B may each include a sacrificial material, such as a nitride.

A channel hole CHH extending through the stack 210S may be formed. For example, channel holes CHH penetrating through the stack 210S may be formed.

Referring to FIG. 3, a memory layer 220 may be conformally formed in the channel hole CHH. Here, the memory layer 220 may be a multilayer. For example, the memory layer 220 may be formed by sequentially forming a blocking layer, a data storage layer, and a tunneling layer.

Subsequently, a preliminary channel layer 230S may be formed in the channel hole CHH. For example, the preliminary channel layer 230S may be conformally formed on the memory layer 220. The preliminary channel layer 230S may include amorphous silicon.

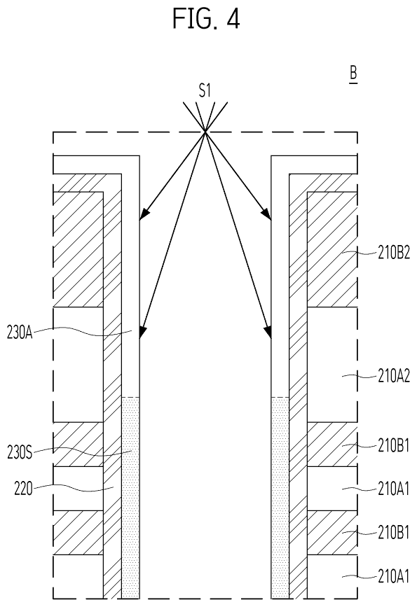

Referring to FIG. 4, a first channel layer 230A may be formed by crystallizing S1 a portion of the preliminary channel layer 230S. For example, the first channel layer 230A may be formed by crystallizing a first portion of the preliminary channel layer 230S shown in FIG. 3 through laser annealing. Here the first portion of the preliminary channel layer 230S may refer to an upper portion of the preliminary channel layer 230S. In such a case, the first channel layer 230A may include polysilicon formed by crystallizing the amorphous silicon. Here, the boundary between the first channel layer 230A and the preliminary channel layer 230S may be between an upper surface and a lower surface of the uppermost first material layer 210A2. However, the present disclosure is not limited thereto, and the boundary between the first channel layer 230A and the preliminary channel layer 230S may be between an upper surface and a lower surface of the uppermost second material layer 210B2.

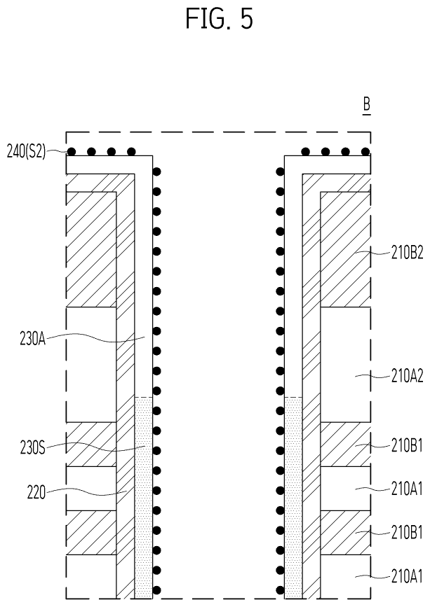

Referring to FIG. 5, the first channel layer 230A and the preliminary channel layer 230S may be doped with metal atoms 240 (S2). For example, the metal atoms 240 may be adsorbed onto surfaces of the first channel layer 230A and the preliminary channel layer 230S by depositing a metal layer by a chemical vapor deposition (CVD) method. In other words, the first channel layer 230A and the preliminary channel layer 230S may be doped with precursors of the metal atoms 240 by a chemical vapor deposition method, and byproducts having volatility may be volatilized, such that only the metal atoms 240 are adsorbed onto the surfaces of the first channel layer 230A and the preliminary channel layer 230S. The metal atoms 240 may increase a grain size of a second channel layer and improve a flow of an electric current, when the second channel layer is formed in a subsequent process. Here, the metal atoms 240 may include nickel atoms.

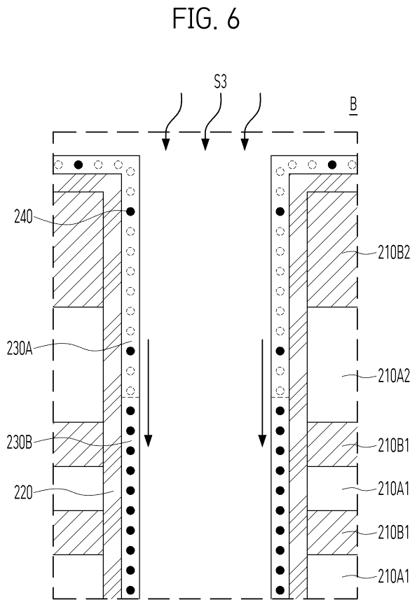

Referring to FIG. 6, a second channel layer 230B may be formed by crystallizing a second portion of the preliminary channel layer 230S. For example, the second channel layer 230B may be formed by annealing S3 the preliminary channel layer 230S. Here, the annealing may be thermal annealing and the second portion of the preliminary channel layer 230S may refer to a lower portion of the preliminary channel layer 230S.

When the preliminary channel layer 230S is crystallized, the metal atoms 240 may move into the first channel layer 230A and the preliminary channel layer 230S. When the preliminary channel layer 230S is crystallized, the metal atoms 240 may move from the first channel layer 230A to the preliminary channel layer 230S, such that the preliminary channel layer 230S may be crystallized to form the second channel layer 230B.

When the preliminary channel layer 230S is crystallized, the metal atoms 240 may move in a direction in which crystallization energy is small. For example, because the nickel atoms might not form nickel silicide by reacting with polysilicon, the nickel atoms might not react with the polysilicon. In other words, because the nickel atoms may form nickel silicide (NiSi₂) by reacting with the amorphous silicon, the nickel atoms may have the lowest free energy at the boundary between the amorphous silicon and the nickel silicide, and may have a small crystallization energy. On the other hand, the crystallization energy may be great in the first channel layer 230A. Accordingly, the nickel atoms may move from the first channel layer 230A to the preliminary channel layer 230S.

When the preliminary channel layer 230S is crystallized, silicon atoms may move in a direction in which the crystallization energy is small. For example, silicon atoms may have the lowest free energy at the boundary between the polysilicon and the nickel silicide (NiSi₂), and may have a small crystallization energy. Accordingly, the silicon atoms may move from the preliminary channel layer 230S to the first channel layer 230A.

In other words, the nickel atoms may move from the first channel layer 230A to the preliminary channel layer 230S, and the silicon atoms may move from the preliminary channel layer 230S to the first channel layer 230A. In such a case, the nickel atoms and the silicon atoms may react with each other to form nickel silicide, and the preliminary channel layer 230S may form the second channel layer 230B while being crystallized with the nickel silicide as a nucleus. Accordingly, the first channel layer 230A may include the metal atoms 240 at a lower concentration than the second channel layer 230A. Alternatively, the first channel layer 230A might not include the metal atoms 240.

When the second channel layer 230B is formed through the metal atoms 240, a grain size of the second channel layer 230B may be greater than that of the first channel layer 230A. For example, the grain size of the second channel layer 230B formed by forming the nickel silicide through the nickel atoms and crystallizing the preliminary channel layer 230S with the nickel silicide as a nucleus may be greater than the grain size of the first channel layer 230A formed by partially crystallizing the preliminary channel layer 230S through the laser annealing. In such a case, the grain size of the second channel layer 230B is relatively large, and thus, an electric current may flow smoothly.

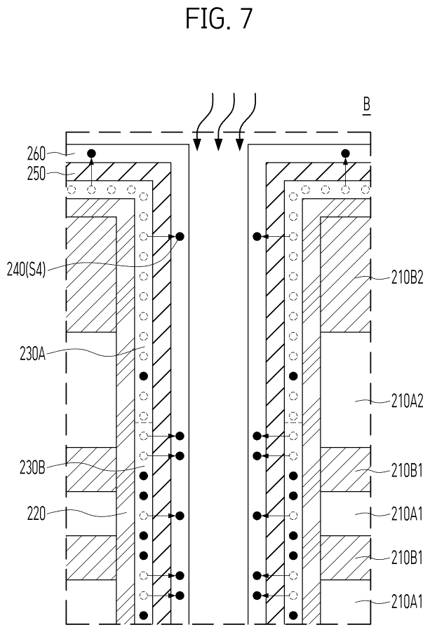

Referring to FIG. 7, a getter layer 260 may be formed on the first channel layer 230A and the second channel layer 230B. For example, the getter layer 260 may be conformally formed over the first channel layer 230A and the second channel layer 230B. Here, the getter layer 260 may include amorphous silicon or silicon nitride. For example, the getter layer 260 may include Si₃N₄.

Subsequently, the metal atoms 240 in the first channel layer 230A and the second channel layer 230B may be removed S4 through the getter layer 260. For example, the metal atoms 240 in the first channel layer 230A and the second channel layer 230B may be moved to the getter layer 260 by annealing the first channel layer 230A and the second channel layer 230B. In a process of removing the metal atoms 240 in the first and second channel layers 230A and 230B using the getter layer 260, high-temperature thermal annealing may be used. For example, the metal atoms 240 in the first and second channel layers 230A and 230B may be moved to the getter layer 260 and removed by annealing the first and second channel layers 230A and 230B at a high temperature of 700° C. or higher. When metal atoms 240 are absent from the first channel layer 230A, only the metal atoms 240 existing in the second channel layer 230B may be removed.

For reference, a process of removing S4 the metal atoms 240 may be repeatedly performed until all of the metal atoms 240 in the first channel layer 230A and the second channel layer 230B are removed. However, the present disclosure is not limited thereto, and even though the process of removing S4 the metal atoms 240 is repeatedly performed, some of the metal atoms 240 may remain in the first channel layer 230A and the second channel layer 230B.

According to an embodiment of the present disclosure, the metal atoms 240 may be used to make the flow of the electric current smooth by increasing the grain size of the second channel layer 230B. In addition, the getter layer 260 may be used to remove the metal atoms 240 in the first channel layer 230A and the second channel layer 230B.

Before the getter layer 260 is formed, a buffer layer 250 may be formed on the first channel layer 230A and the second channel layer 230B. The buffer layer 250 may include a different material from the getter layer 260. The buffer layer 250 may include a material having a selectivity with respect to phosphoric acid. The buffer layer 250 may include silicon carbonitride or silicon carbonate. For example, the buffer layer 250 may include SiCN or SiCO.

Subsequently, the getter layer 260 may be removed. For example, the getter layer 260 may be removed using phosphoric acid. The buffer layer 250 may be formed between the channel layers 230A and 230B and the getter layer 260 to protect the channel layers 230A and 230B in a process of removing the getter layer 260. For example, when the buffer layer 250 is absent, the first channel layer 230A including the polysilicon may be damaged when the getter layer 260 is removed. According to an embodiment of the present disclosure, the buffer layer 250 may include the material having a selectivity with respect to the phosphoric acid, and may thus prevent the channel layers 230A and 230B from being damaged in the process of removing the getter layer 260.

Subsequently, the buffer layer 250 may be removed. First, an oxide layer may be formed by oxidizing the buffer layer 250. Subsequently, the oxidized buffer layer 250 may be removed with hydrogen fluoride.

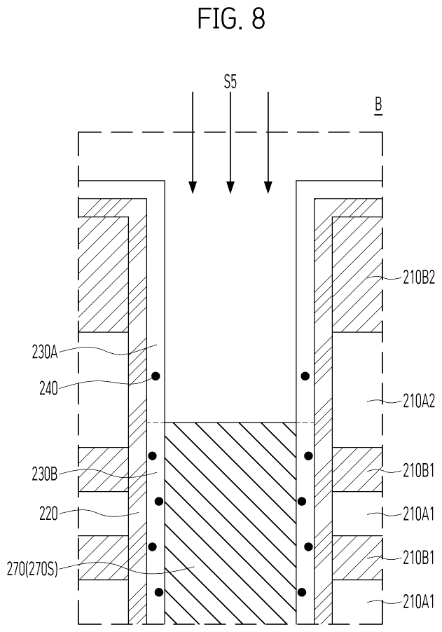

Referring to FIG. 8, an insulating core 270 may be formed. First, a preliminary insulating core 270S may be formed on the first channel layer 230A and the second channel layer 230B. The preliminary insulating core 270S may be formed to fill an inner portion of the channel hole CHH. Subsequently, the insulating core 270 may be formed by removing S5 a portion of the preliminary insulating core 270S up to a level corresponding to the boundary between the first channel layer 230A and the second channel layer 230B. Here, a dry cleaning method may be used.

An annealing process may be performed in a process of forming the channel layer by annealing the preliminary channel layer. In such a process, metal silicides and metal silicide clusters may be formed in the channel layer. Thereafter, in a process of removing the metal atoms in the channel layer through the getter layer, the metal silicides and the metal silicide clusters may remain. Subsequently, the dry cleaning method may be used in a process of forming the insulating core. When the metal silicides and the metal silicide clusters remain in the vicinity of an upper surface of the channel layer, silicon atoms may be agglomerated, and the vicinity of the upper surface of the channel layer may be damaged in a dry cleaning process.

According to an embodiment of the present disclosure, the first channel layer 230A corresponding to the vicinity of the upper surface of the channel layer may be formed before the second channel layer 230B is formed. For example, the first channel layer 230A may be formed by targeting a portion of the preliminary channel layer 230S and partially crystallizing the preliminary channel layer 230S through the laser annealing. Here, the first channel layer 230A may include the polysilicon formed by crystallizing the amorphous silicon. Subsequently, the first channel layer 230A and the preliminary channel layer 230S may be doped with the metal atoms 240. Subsequently, in a process of annealing the preliminary channel layer 230S to form the second channel layer 230B, the metal atoms 240 in the first channel layer 230A may move to the preliminary channel layer 230S corresponding to a portion that will become the second channel layer 230B. In other words, the first channel layer 230A might not include the metal atoms 240 or may include the metal atoms 240 at a relatively lower concentration than the second channel layer 230B.

In such a case, in the first channel layer 230A corresponding to the vicinity of the upper surface of the channel layer, the metal silicide clusters might not be formed, an amount of the metal silicide clusters may be reduced, or the silicon atoms might not be agglomerated. Accordingly, even though the dry cleaning method is used in the process of forming the insulating core 270, the first channel layer 230A might not be damaged.

Referring to FIGS. 9A and 9B, a capping layer 280 may be formed on the insulating core 270. First, a preliminary capping layer 280S may be formed on the insulating core 270. The preliminary capping layer 280S may be formed to fill the inner portion of the channel hole CHH. Subsequently, the preliminary capping layer 280S may be planarized S6 until the uppermost first material layer 210A2 is exposed. For example, the preliminary capping layer 280S and the uppermost second material layer 210B2 may be planarized until the uppermost first material layer 210A2 is exposed. Consequently, the capping layer 280 may be formed. Here, the capping layer 280 may include polysilicon or the like.

Subsequently, the remaining second material layers 210B1 of the stack 210 may be replaced with third material layers 210C. The remaining second material layers 210B1 may be removed through a slit (not illustrated) extending through the stack 210, and the third material layers 210C may be formed. Here, the third material layers 210C may each include a conductive material, such as tungsten. Consequently, a gate structure 210G including the first material layers 210A and the third material layers 210C that are alternately stacked may be formed. When the remaining second material layers 210B1 each include a conductive material, a replacement process may be omitted. In such a case, the stack 210 may be used as the gate structure 210G.

For reference, a case where the first channel layer 230A remains has been described in the present embodiment, but the first channel layer 230A may be removed in a process of forming the capping layer 280. For example, the first channel layer 230A and the second channel layer 230B may be formed as they are, the insulating core 270 may be formed so that an upper surface thereof is below the lower surface of the uppermost first material layer 210A2, and the preliminary capping layer 280S may be planarized until the first channel layer 230A is removed. In such a case, the channel layer may be composed of only the second channel layer 230B.

According to the manufacturing method described above, the first channel layer 230A adjacent to the upper surface of the channel layer may be first formed. In other words, the first channel layer 230A may be formed by partially crystallizing the preliminary channel layer 230S. In such a case, in a subsequent process, the first channel layer 230A might not include the metal atoms 240, and the metal silicide clusters might not exist or an amount of the metal silicide clusters may be reduced and the silicon atoms might not be agglomerated, in the first channel layer 230A. Accordingly, even though the dry cleaning method is used in the process of forming the insulating core 270, the first channel layer 230A might not be damaged.

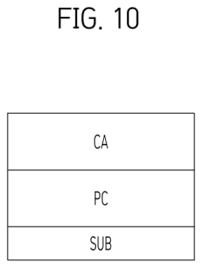

FIG. 10 is a diagram for describing a semiconductor device in accordance with an embodiment. Hereinafter, content already described is not repeated.

Referring to FIG. 10, a semiconductor device may include a substrate SUB, a peripheral circuit PC, and a memory cell array CA. Here, the peripheral circuit PC and the memory cell array CA may be formed over the same substrate.

The substrate SUB may include a semiconductor material. As an example, the semiconductor material may include at least one of a group IV semiconductor, a group III-V compound semiconductor, and a group II-VI compound semiconductor. Here, the group IV semiconductor may include single crystal silicon (Si), polycrystalline silicon, germanium (Ge), or silicon germanium (SiGe). The group III-V compound semiconductor may include GaAs, GaN, GaP, GaAsP, GaInAsP, AlAs, AlGa, InP, InSb, or InGaAs. The group II-VI compound semiconductor may include ZnS, ZnO, or CdS.

The substrate SUB may include a dielectric layer. The substrate SUB may be a silicon-on-insulator (SOI) substrate, a germanium-on-insulator (GeOI) substrate, or a glass substrate. The substrate SUB may include an organic material. As an example, the substrate SUB may include graphene.

The substrate SUB may be a bulk wafer or an epitaxial layer grown by a selective epitaxial growth (SEG) method. The substrate SUB may be a layer formed by a metal induced lateral crystallization (MILC) method and may partially include metal. The substrate SUB may have a single crystalline, polycrystalline, or amorphous state. The substrate SUB may include group II, group III, group IV, group V, or group VI impurities. As an example, the substrate SUB may include an n-well region doped with n-type impurities and/or a p-well region doped with p-type impurities.

The peripheral circuit PC may be between the substrate SUB and the memory cell array CA. The peripheral circuit PC may include a row decoder, a column decoder, a page buffer, a logic circuit, a control circuit, a sense amplifier, an input/output circuit, and the like. As an example, the peripheral circuit PC may include one or more of N-channel metal oxide semiconductor (NMOS) transistors, P-channel metal oxide semiconductor (PMOS) transistors, resistors, capacitors, and the like. The peripheral circuit PC may further include an interconnection structure. The interconnection structure may be used as a path for transmitting operating voltages, and may include a contact plug, a wiring line, and the like.

The memory cell array CA may include memory cells. As an example, the memory cell array CA may include memory strings connected between a source line and a bit line, and each memory string may include stacked memory cells. As an example, the memory cell array CA may include memory cells connected between a word line and the bit line. The memory cell array CA may further include an interconnection structure.

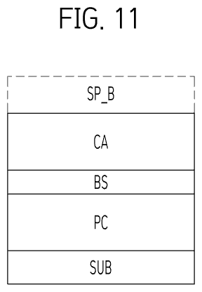

FIG. 11 is a diagram for describing a semiconductor device in accordance with an embodiment. Hereinafter, content already described is not repeated.

Referring to FIG. 11, a semiconductor device may include a substrate SUB, a peripheral circuit PC, a bonding structure BS, and a memory cell array CA. Here, the peripheral circuit PC and the memory cell array CA may be formed over separate substrates and then bonded to each other. The semiconductor device may further include a support base SP_B.

The substrate SUB may be used as a support in a process of forming the peripheral circuit PC. The support base SP_B may be used as a support in a process of forming the memory cell array CA. As an example, a first wafer including the memory cell array CA and a second wafer including the peripheral circuit PC may be manufactured and then electrically connected to each other by the bonding structure BS. After the first wafer and the second wafer are bonded to each other, the support base SP_B of the first wafer may be at least partially removed. The support base SP_B may be completely removed or may partially remain on the memory cell CA array.

The support base SP_B may be a semiconductor substrate, an insulating substrate, a silicon-on-insulator (SOI) substrate, a germanium-on-insulator (GeOI) substrate, or the like. The support base SP_B may be a bulk wafer, an epitaxial layer grown by a selective epitaxial growth (SEG) method, or a layer formed by a metal induced lateral crystallization (MILC) method. The support base SP_B may have a single crystalline, polycrystalline, or amorphous state. The support base SP_B may include group II, group III, group IV, group V, or group VI impurities.

The bonding structure BS may be used to connect the memory cell array CA and the peripheral circuit PC to each other. As an example, the bonding structure BS may bond the memory cell array CA and the peripheral circuit PC to each other by a wafer-on-wafer bonding method, a chip-on-wafer bonding method, a chip-on-chip bonding method, or the like. The bonding structure BS may include a bonding pad, a bonding interface, and the like. The bonding pad may include metal, such as copper, aluminum, and/or alloys thereof. The bonding interface may include a nonmetal-nonmetal interface, a metal-metal interface, or the like. The memory cell array CA and the peripheral circuit PC may be electrically connected to each other by the bonding structure BS.

For reference, it is also possible for interconnection structures included in the memory cell array CA and/or the peripheral circuit PC to be used as the bonding structure BS. As an example, an interconnection structure included in the memory cell array CA and an interconnection structure included in the peripheral circuit PC may be directly bonded to each other. In such a case, a bit line, a source line, and the like, may be used as the bonding structure without a separate bonding pad.

Other configurations may be the same as or similar to those described above with reference to FIG. 10.

It is also possible for a semiconductor device to have a structure in which embodiments described above with reference to FIGS. 10 and 11 are combined with each other or have a partially modified structure. In embodiments described with reference to FIGS. 10 and 11, locations of the memory cell array CA and the peripheral circuit PC may be changed. At least one memory cell array CA and/or at least one peripheral circuit PC may be additionally bonded to each other in an embodiment described with reference to FIG. 10. As an example, a portion of the peripheral circuit PC may be in the memory cell array CA.

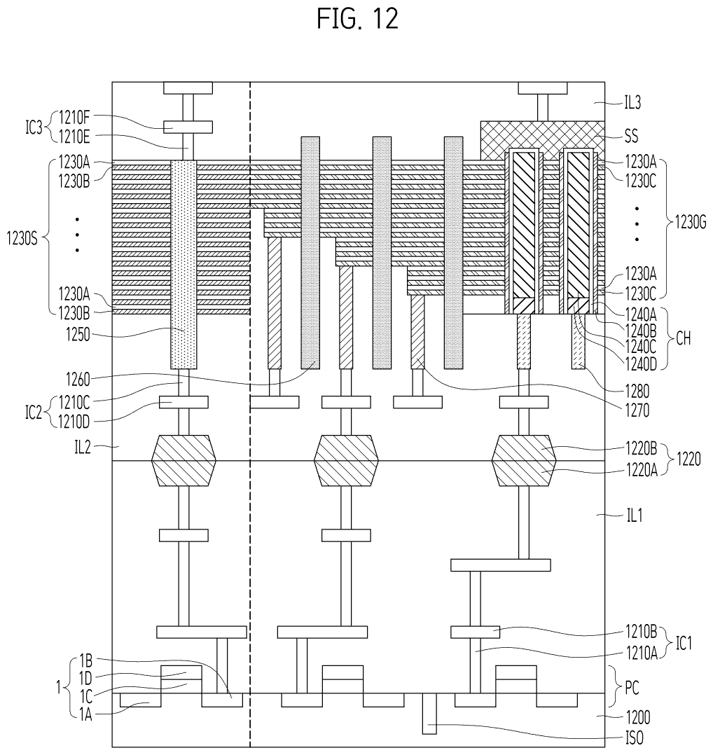

FIG. 12 is a diagram for describing a semiconductor device in accordance with an embodiment. Hereinafter, content already described is not repeated.

Referring to FIG. 12, a semiconductor device may include a substrate 1200, a peripheral circuit PC, a source structure SS, a bonding structure 1220, a stack 1230S, a gate structure 1230G, channel structures CH, a through plug 1250, supports 1260, a first contact via 1270, second contact vias 1280, an element isolation layer ISO, a first interconnection structure IC1, a second interconnection structure IC2, a third interconnection structure IC3, a first interlayer insulating layer IL1, a second interlayer insulating layer IL2, and a third interlayer insulating layer IL3.

The peripheral circuit PC may be on the substrate 1200. The peripheral circuit PC may include a transistor 1. The transistor 1 may include junctions 1A and 1B, a gate electrode 1D, and a gate insulating layer 1C. The element isolation layer ISO may be in the substrate 1200, and an active region of the transistor 1 may be defined by the element isolation layer ISO.

The first interconnection structure IC1 may be on the peripheral circuit PC. The first interconnection structure IC1 may be in the first interlayer insulating layer IL1. Here, the first interlayer insulating layer IL1 may be on the substrate 1200. The first interconnection structure IC1 may include first vias 1210A and first wiring lines 1210B. The first interconnection structure IC1 may include a conductive material, such as tungsten. The first interlayer insulating layer IL1 may include an insulating material, such as an oxide or a nitride.

The bonding structure 1220 may be over the peripheral circuit PC. For example, the bonding structure 1220 may be on the first interconnection structure IC1. The bonding structure 1220 may include first bonding pads 1220A and second bonding pads 1220B. The first bonding pads 1220A may be in the first interlayer insulating layer IL1. The second bonding pads 1220B may be on the first bonding pads 1220A and may be in the second interlayer insulating layer IL2. Here, the second interlayer insulating layer IL2 may be on the first interlayer insulating layer IL1. The bonding structure 1220 may include a conductive material, such as copper. The second interlayer insulating layer IL2 may include an insulating material, such as an oxide.

The second interconnection structure IC2 may be on the bonding structure 1220. The second interconnection structure IC2 may be in the second interlayer insulating layer IL2. The second interconnection structure IC2 may include second vias 1210C and second wiring lines 1210D. The second interconnection structure IC2 may be connected to the bonding structure 1220. For example, at least one of the second vias 1210C may be connected to the second bonding pad 1220B. The second interconnection structure IC2 may include a conductive material, such as tungsten.

The stack 1230S may be over the bonding structure 1220. For example, the stack 1230S may be on the second interconnection structure IC2. The stack 1230S may include insulating layers 1230A and sacrificial layers 1230B that are alternately stacked. The gate structure 1230G may be located at a level corresponding to the stack 1230S. The gate structure 1230G may include insulating layers 1230A and conductive layers 1230C that are alternately stacked. The gate structure 1230G may include an inverted staircase structure in which lower surfaces of the conductive layers 1230C are exposed.

For reference, the terms “upper” and “lower” may be relative concepts for convenience of explanation. For example, the gate structure 1230G may include a staircase structure in which upper surfaces of the conductive layers 1230C are exposed. A state in which the gate structure 1230G is rotated has been illustrated in FIG. 12. In other words, the gate structure 1230G including the inverted staircase structure has been illustrated in FIG. 12.

The through plug 1250 may extend through the stack 1230S and into the second interlayer insulating layer IL2. The through plug 1250 may be electrically connected to the peripheral circuit PC through the bonding structure 1220. For example, the through plug 1250 may be connected to the bonding structure 1220 through the second interconnection structure IC2, and may be electrically connected to the peripheral circuit PC through the bonding structure 1220. The through plug 1250 may include a conductive material, such as tungsten. However, the present disclosure is not limited thereto, and the through plug 1250 may be a support and may include an insulating material, such as an oxide.

The channel structures CH may extend through the gate structure 1230G and into the source structure SS. Here, the source structure SS may be on the gate structure 1230G. Each of the channel structures CH may include at least one of a channel layer 1240A, a memory layer 1240B surrounding the channel layer 1240A, an insulating core 1240C inside the channel layer 1240A, and a capping layer 1240D on the insulating core 1240C. Here, the channel layer 1240A may be connected to the source structure SS.

For reference, the channel structures CH may correspond to the channel structures CH of FIGS. 1A and 1B, and the channel layer 1240A, the memory layer 1240B, the insulating core 1240C, and the capping layer 1240D may correspond to the channel layer 120, the memory layer 130, the insulating core 140, and the capping layer 150 of FIGS. 1A and 1B, respectively.

The supports 1260 may extend through the gate structure 1230G and into the third interlayer insulating layer IL3. Here, the third interlayer insulating layer IL3 may be on the gate structure 1230G and/or the stack 1230S. The supports 1260 may each include an insulating material, such as an oxide. The third interlayer insulating layer IL3 may include an insulating material, such as an oxide.

The first contact vias 1270 may be respectively connected to the conductive layers 1230C of the gate structure 1230G. For example, the first contact vias 1270 may extend into the second interlayer insulating layer IL2 and be respectively connected to the conductive layers 1230C whose lower surfaces are exposed, through the inverted staircase structure of the gate structure 1230G. The first contact vias 1270 may each include a conductive material, such as tungsten.

The second contact vias 1280 may be connected to the channel structures CH, respectively. For example, the second contact vias 1280 may extend into the second interlayer insulating layer IL2 and may be respectively connected to the channel layers 1240A of the channel structures CH. The second contact vias 1280 may each include a conductive material, such as tungsten.

The third interconnection structure IC3 may be in the third interlayer insulating layer IL3. The third interconnection structure IC3 may include third vias 1210E and third wiring lines 1210F. At least one of the third vias 1210E may be connected to the first contact via 1270. At least one of the third vias 1210E may be connected to the source structure SS. At least one of the third wiring lines 1210F may be connected to the third contact via 1210E. The third interconnection structure IC3 may include a conductive material, such as tungsten.

According to the structure described above, the semiconductor device may include the bonding structure 1220. The bonding structure 1220 may be over the peripheral circuit PC and may be electrically connected to the peripheral circuit PC.

Although embodiments according to the technical idea of the present disclosure have been described above with reference to the accompanying drawings, this is only for explaining the embodiments according to the concept of the present disclosure, and the present disclosure is not limited to the above embodiments. Various types of substitutions, modifications, and changes for the embodiments may be made by those skilled in the art, to which the present disclosure pertains, without departing from the technical idea of the present disclosure defined in the following claims, and it should be construed that these substitutions, modifications, and changes belong to the scope of the present disclosure.

What is claimed is:

1. A semiconductor device comprising:
a gate structure including alternately stacked insulating layers and conductive layers;
a channel layer extending through the gate structure, the channel layer including a first portion including metal atoms at a first concentration and a second portion including metal atoms at a second concentration different from the first concentration;
an insulating core inside the channel layer; and
a capping layer on the insulating core,
wherein the first portion is on the second portion, and the boundary between the first portion and the second portion is between an upper surface and a lower surface of an uppermost insulating layer of the insulating layers.

2. The semiconductor device of claim 1, wherein the capping layer is at a level corresponding to the first portion, and
the insulating core is at a level corresponding to the second portion.

3. The semiconductor device of claim 1, wherein the first concentration is lower than the second concentration.

4. The semiconductor device of claim 1, wherein the first portion has a first grain size, and
wherein the second portion has a second grain size different from the first grain size.

5. The semiconductor device of claim 4, wherein the second grain size is greater than the first grain size.

6. The semiconductor device of claim 1, wherein the first portion includes polysilicon that does not include metal silicide, and
the second portion includes polysilicon that includes metal silicide.

7. The semiconductor device of claim 6, wherein the metal silicide comprises nickel silicide.

8. The semiconductor device of claim 1, wherein the metal atoms comprise nickel atoms.

9. A semiconductor device comprising:
a gate structure including alternately stacked insulating layers and conductive layers;
a channel layer extending through the gate structure, the channel layer including a first portion having a first grain size and a second portion having a second grain size different from the first grain size;
an insulating core inside the channel layer at a level corresponding to the second portion; and
a capping layer on the insulating core at a level corresponding to the first portion.

10. The semiconductor device of claim 9, wherein the boundary between the first portion and the second portion is between an upper surface and a lower surface of an uppermost insulating layer of the insulating layers.

11. The semiconductor device of claim 9, wherein the second grain size is greater than the first grain size.

12. The semiconductor device of claim 9, wherein the first portion includes metal atoms at a first concentration, and
wherein the second portion includes metal atoms at a second concentration different from the first concentration.

13. The semiconductor device of claim 12, wherein the first concentration is lower than the second concentration.

14. The semiconductor device of claim 12, wherein the metal atoms comprise nickel atoms.

15. The semiconductor device of claim 9, wherein the first portion includes polysilicon that does not include metal silicide, and
the second portion includes polysilicon that includes metal silicide.

16. The semiconductor device of claim 15, wherein the metal silicide comprises nickel silicide.

17. A manufacturing method of a semiconductor device, the manufacturing method comprising:
forming a stack by alternately stacking first material layers and second material layers;
forming a channel hole extending through the stack;
forming a preliminary channel layer in the channel hole;
forming a first channel layer by crystallizing a first portion of the preliminary channel layer;
doping the first channel layer and the preliminary channel layer with metal atoms;
forming a second channel layer by crystallizing a second portion the preliminary channel layer;
forming an insulating core inside the first channel layer and the second channel layer; and
forming a capping layer on the insulating core.

18. The manufacturing method of claim 17, wherein forming the first channel layer includes selectively crystalizing the first portion of the preliminary channel layer so that the boundary between the first channel layer and the preliminary channel layer is between an upper surface and a lower surface of an uppermost first material layer of the first material layers.

19. The manufacturing method of claim 18, wherein the preliminary channel layer includes amorphous silicon, and
wherein the first channel layer includes polysilicon that does not include metal silicide.

20. The manufacturing method claim 19, wherein the metal silicide comprises nickel silicide.

21. The manufacturing method of claim 17, wherein doping the first channel layer and the preliminary channel layer with the metal atoms includes adsorbing the metal atoms onto surfaces of the first channel layer and the preliminary channel layer by depositing a metal layer by a chemical vapor deposition (CVD) method.

22. The manufacturing method of claim 21, wherein crystalizing the first portion of the preliminary channel layer includes the metal atoms moving into the first channel layer and the preliminary channel layer.

23. The manufacturing method of claim 17, wherein crystalizing the second portion of the preliminary channel layer includes the metal atoms moving from the first channel layer to the second portion of the preliminary channel layer so that the second portion of the preliminary channel layer is crystallized.

24. The manufacturing method of claim 17, wherein the preliminary channel layer includes amorphous silicon, and
wherein the second channel layer includes polysilicon that includes metal silicide.

25. The manufacturing method claim 24, wherein the metal silicide comprises nickel silicide.

26. The manufacturing method of claim 17, further comprising:
forming a getter layer on the first channel layer and the second channel layer;
removing the metal atoms in the first channel layer and the second channel layer through the getter layer; and
removing the getter layer.

27. The manufacturing method of claim 26, wherein removing the metal atoms includes annealing the first channel layer and the second channel layer so that the metal atoms in the first channel layer and the second channel layer are moved to the getter layer.

28. The manufacturing method of claim 26, wherein removing the getter layer comprises removing the getter layer with phosphoric acid.

29. The manufacturing method of claim 26, wherein the getter layer includes amorphous silicon or silicon nitride.

30. The manufacturing method of claim 26, further comprising:
forming a buffer layer on the first channel layer and the second channel layer before the forming of the getter layer; and
removing the buffer layer after removing the getter layer.

31. The manufacturing method of claim 30, wherein the buffer layer includes a material having a selectivity with respect to phosphoric acid.

32. The manufacturing method of claim 31, wherein the buffer layer includes silicon carbonitride or silicon carbonate.

33. The manufacturing method of claim 30, wherein removing the buffer layer comprises:
oxidizing the buffer layer; and
removing the oxidized buffer layer with hydrogen fluoride.

34. The manufacturing method of claim 17, wherein forming the insulating core comprises forming a preliminary insulating core on the first channel layer and the second channel layer.

35. The manufacturing method of claim 34, wherein forming the insulating core comprises forming the insulating core by removing the preliminary insulating core up to a level corresponding to the boundary between the first channel layer and the second channel layer by a dry cleaning method.

36. The manufacturing method of claim 17, wherein the metal atoms comprise nickel atoms.
